(19) United States
(12) Patent Application Publication
(10) Pub. No.: US 2013/0307005 A1
(43) Pub. Date: Nov. 21, 2013

(54) Low Cost Surface Mount Packaging Structure for Semiconductor Optical Device and Packaging Method Therefor

(71) Applicant: INNOLIGHT TECHNOLOGY (SUZHOU) LTD., Jiangsu (CN)

(72) Inventors: Weilong LI, Jiangsu (CN); Yuzhou SUN, Jiangsu (CN); Pan WANG, Jiangsu (CN); Peng HUANG, Jiangsu (CN); Gaohong SHI, Jiangsu (CN); Sheng LIU, Jiangsu (CN)

(73) Assignee: INNOLIGHT TECHNOLOGY (SUZHOU) LTD., Jiangsu (CN)

(21) Appl. No.: 13/837,001

(22) Filed: Mar. 15, 2013

(30) Foreign Application Priority Data
May 18, 2012 (CN) 201210154315.2

(51) Int. Cl. H01L 31/0232; H01L 31/18; H01L 33/58

(52) U.S. Cl. CPC H01L 31/0232; H01L 33/58; H01L 31/18
USPC 257/98; 257/432; 438/27; 438/65

(57) ABSTRACT

A surface mount packaging structure for semiconductor optical device and packaging method. A semiconductor optical device, disposed on a substrate, is electrically connected with a substrate through wires. A lower surface of the substrate is fixed on an upper surface of a flexible printed board that is provided with internal leads and external leads. The internal leads are electrically connected with the substrate through wires. A lower surface of the flexible printed board is fixed on a base board. A glass baffle is provided to form a window in front of a light-emitting or light-receiving surface of the semiconductor optical device. A focusing lens is adhered to the window of the glass baffle and is coupled with an optical path of the semiconductor optical device. The substrate and the semiconductor optical device thereon, the wires, and the internal leads on the flexible printed board are encased into packaging material.

### TECHNICAL FIELD

The present invention relates to low cost surface mount packaging structure, with a flexible printed board as the carrier, for semiconductor optical device, and packaging method therefor.

### BACKGROUND OF THE INVENTION

In the information age today, electronic products are widely used in various fields of the society, which brings unprecedented changes in people's way of life and way of production. Along with the continuing development of the electronic technology, electronic products have been brought into being, which are more human friendly and more powerful. In order to meet the requirements of miniaturization, low cost, high density and multifunction for electronic products, with respect to chip packaging, packaging technologies have been developed to encase multiple chips in one package, such as Multi-chip-module technology, Stack Die technology and so on. Therefore, how to realize packaging structure with low cost and high density has become an important research subject.

### SUMMARY OF THE INVENTION

The present invention aims at overcoming the defects in the prior art and providing low cost surface mount packaging structure for semiconductor optical device and a packaging method therefor.

The present invention is carried out by the following technical schemes: low cost surface mount packaging structure for semiconductor optical device comprises a base board, a flexible printed board and a substrate; at least one semiconductor optical device is disposed on the substrate; the semiconductor optical device is electrically connected with the substrate through wires; a lower surface of the substrate is adhered to and fixed on an upper surface of the flexible printed board; the flexible printed board is provided with internal leads and external leads; the internal leads are electrically connected with the substrate through wires; a lower surface of the flexible printed board is adhered to and fixed on the base board; a glass baffle is provided to form a window in front of a light-emitting surface or a light-receiving surface of the semiconductor optical device; a focusing lens is adhered to the window of the glass baffle and is coupled into an optical path of the semiconductor optical device; the substrate and the semiconductor optical device thereon, the wires, and the internal leads on the flexible printed board are encased with packaging material.

Preferably, in the low cost surface mount packaging structure for semiconductor optical device described above, the semiconductor optical device is a photographic device or a luminescent device.

Preferably, in the low cost surface mount packaging structure for semiconductor optical device described above, the substrate comprises an upper layer and a lower layer; the lower layer is made of material with high heat conductivity and low Thermal Coefficient of Expansion; the upper layer is a wire routing layer, which is electrically connected with the semiconductor optical device on the substrate, and is made of conductive material.

Preferably, in the low cost surface mount packaging structure for semiconductor optical device described above, the material with high heat conductivity and low Thermal Coefficient of Expansion is aluminium nitride; and the conductive material is gold.

Preferably, in the low cost surface mount packaging structure for semiconductor optical device described above, the semiconductor optical device is connected with the substrate by means of eutectic welding and wire bonding.

Preferably, in the low cost surface mount packaging structure for semiconductor optical device described above, the substrate is adhered to the flexible printed board with conductive adhesive; the flexible printed board is adhered to the base board with conductive adhesive, and wherein the conductive adhesive is silver paste.

Preferably, in the low cost surface mount packaging structure for semiconductor optical device described above, one substrate or multiple substrates arranged are disposed on the flexible printed board, of which the internal leads are electrically connected with a wire routing layer of the substrate.

Preferably, in the low cost surface mount packaging structure for semiconductor optical device described above, the base board is made of tungsten copper; the packaging material is silica gel; and the wires are made of gold.

A packaging method for the low cost surface mount packaging structure for semiconductor optical device of the present invention comprises the following steps:

step 1, bonding a semiconductor optical device by means of eutectic welding and wire bonding onto a wire routing layer of a substrate;

step 2, electrically connecting the semiconductor optical device with the substrate through wires by means of wire bonding;

step 3, fixing a lower surface of a flexible printed board onto a base board with conductive adhesive; and getting the adhesive cured;

step 4, fixing a lower layer of the substrate onto an upper surface of the flexible printed board with conductive adhesive; and getting the adhesive cured;

step 5, electrically connecting internal leads of the flexible printed board with the wire routing layer of the substrate through wires by means of wire bonding;

step 6, installing a glass baffle to form a window in front of a light-emitting surface or a light receiving surface of the semiconductor optical device for light inputting or light outputting;

step 7, encasing the semiconductor optical device, the wires on a surface where the semiconductor optical device is disposed, the wire routing layer of the substrate and the internal leads of the flexible printed board with packaging material, packaging material fills all space in the optical path evenly; and getting the packaging material cured; and

step 8, adhere a focusing lens to the window of the glass baffle; and coupling the focusing lens into the optical path of the semiconductor optical device.

Preferably, in the packaging method described above, the wires in step 2 and step 5 are made of gold; the conductive adhesive in step 3 and step 4 is silver paste; and the packaging material in step 7 is silica gel.

### BRIEF DESCRIPTION OF THE DRAWINGS

The present invention will be described in more details with reference to the accompanying figures.

FIG. 1 is a schematic view illustrating the light outputting from a lateral surface of the surface mount packaging structure for semiconductor optical device of the present invention;

FIG. 2 is a top view illustrating the light outputting from a lateral surface of the surface mount packaging structure for semiconductor optical device of the present invention.

### DETAILED DESCRIPTION OF THE PREFERRED EMBODIMENTS

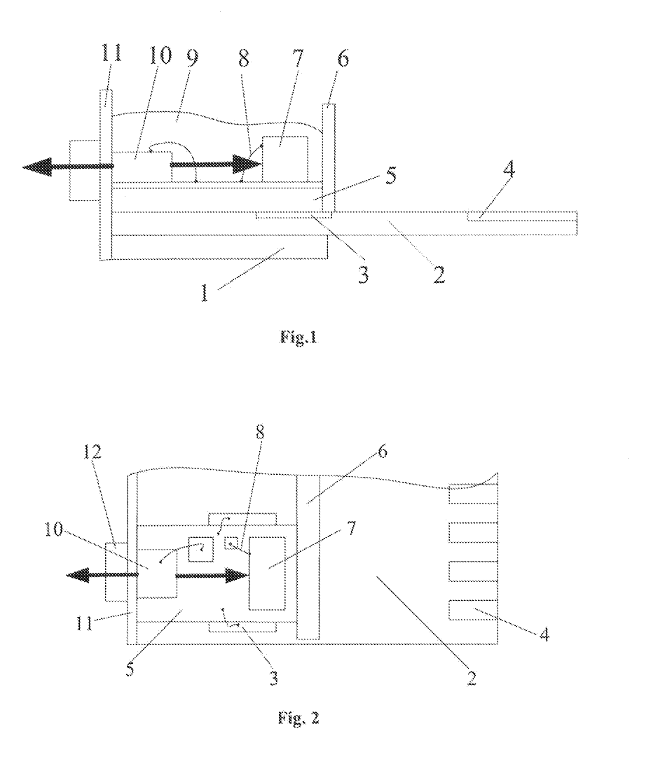

As shown in FIGS. 1 and 2, the low cost surface mount packaging structure for semiconductor optical device comprises a base board 1, a flexible printed board 2 and a substrate 5. A first semiconductor optical device 7 and a second semiconductor optical device 10 are disposed on the substrate 5. The first semiconductor optical device 7 is electrically connected with the substrate 5 through wires 8, and the second semiconductor optical device 10 is electrically connected with the substrate 5 through wires, wherein the wires are made of gold. The lower surface of the substrate 5 is adhered to and fixed on the upper surface of the flexible printed board 2. The flexible printed board 2 is provided with internal leads 3 and external leads 4. The internal leads 3 are electrically connected with the substrate 5 through wires made of gold. The lower surface of the flexible printed board 2 is adhered to and fixed on the base board 1 made of tungsten copper. The base board 1 has good coefficient of thermal conductivity, which enables heat generated by the optical devices to be dissipated outwards effectively, and has TCE (Thermal Coefficient of Expansion) approximate to those of the optical devices. A glass baffle 11 is provided to form a window in front of the light-emitting surface or light-receiving surface of the first semiconductor optical device 7 and the second semiconductor optical device 10. The glass baffle 11 provides a window for the optical path, enabling the light signal to transmit outwards from the light-emitting surface or enabling the light from outside to arrive at the light-receiving surface. The glass baffle 11 together with a bounding wall 6 surrounds the semiconductor optical devices, wires and internal leads of the flexible printed board on the substrate. A focusing lens 12 is adhered to the window of the glass baffle 11 and is coupled into the optical path of the semiconductor optical device. The focusing lens functions to collimate or focus the transmission light in the optical path. All of the substrate 5, the first semiconductor optical device 7 and the second semiconductor optical device 10 thereon, the wires, and the internal leads of the flexible printed board are encased with packaging material 9. The packaging material is silica gel, has high light transmittance, high reliability and low stress. The packaging material has refractive index matching with that of the glass baffle, so as to reduce the reflection of the light on surfaces of different mediums and to diminish the divergence angle of light beam. The packaging material is liquid at ambient temperature and can be cured.

The first semiconductor optical device 7 is a photographic device, and the second semiconductor optical device 10 is a luminescent device. The luminescent semiconductor optical device is an Edge-Emitting FP laser or an Edge-Emitting DFB laser, which has a front light-emitting surface and a rear light-emitting surface in its cavity resonator. The front light-emitting surface for generating light signal is plated with antireflection coating. The rear light-emitting surface is plated with reflectance coating, and the light generated for detecting the working state of the laser is weaker. The upper surface of the luminescent semiconductor optical device is provided with an electrical connection point for electrically connecting to the substrate.

The first semiconductor optical device 7 and the second semiconductor optical device 10 are connected with the substrate 5 through wires by means of eutectic welding and wire bonding, and the conductive adhesive is silver paste. Compared with the traditional adhesive bonding with epoxy conductive adhesive, the eutectic welding has the advantages of high heat conductivity, low resistance, quick heat conducting, high reliability and large shearing force after adhering, and so on.

The substrate 5 comprises an upper layer and a lower layer. The lower layer is made of aluminium nitride, which has high heat conductivity and low TCE. The upper layer is a wire routing layer, which is electrically connected with the semiconductor optical devices on the substrate, and which is made of conductive material, specifically, gold.

One substrate or multiple substrates arranged are disposed on the flexible printed board 2, the internal leads 3 of the flexible printed board 2 are electrically connected with the wire routing layer of the substrate.

The packaging process of the low cost surface mount packaging structure for semiconductor optical device is as follows:
1. Bond the first semiconductor optical device 7 and the second semiconductor optical device 10 onto the wire routing layer of the substrate 5 by means of eutectic welding and wire bonding;
2. Electrically connect the first semiconductor optical device 7 and the second semiconductor optical device 10 with the substrate 5 through wires made of gold by means of wire bonding;
3. Fix the lower surface of the flexible printed board 2 on the base board 1 with adhesive (which is silver paste), and get the adhesive cured;
4. Fix the lower layer of the substrate 5 on the upper surface of the flexible printed board 2 with adhesive (which is silver paste), and get the adhesive cured;
5. Electrically connect the internal leads 3 of the flexible printed board with the wire routing layer of the substrate through wires made of gold by means of wire bonding;
6. Install the glass baffle 11 in front of the light-emitting surface of the second semiconductor optical device 10 to form the window for inputting light or outputting light;
7. Encase the semiconductor optical devices, the wires on the surface where the semiconductor optical devices are disposed, the wire routing layer of the substrate and the internal leads of the flexible printed board with the packaging material 9 (which is silica gel), and fills all space in the optical path evenly with the packaging material, and get the packaging material cured;
8. Adhere the focusing lens 12 to the window of the glass baffle 11; and couple the focusing lens into the optical path of the semiconductor optical devices.

As described above, in the present invention, with the flexible printed board as the carrier and with the use of surface mount technology and wire bonding technology, two ends of each wire are respectively connected to the semiconductor optical devices and the flexible printed board directly. The present invention is beneficial to the transmission of high frequency signal. All operations are stacking operations performed only on one surface of each element, which enables operations for multiple semiconductor optical devices combined and arranged, and which can be performed easily. The present invention reduces the requirements for space for packaging chip and reduces the volume, has low requirements for the packaging machine, and low cost for packaging. The present invention is beneficial to extension, integration and production on a large scale.

The preferred embodiments described above are not restricted. It will be understood by those skilled in the art that various modifications and improvements may be made therein without departing from the scope of the invention.

What is claimed is:

1. Low cost surface mount packaging structure for semiconductor optical device, comprising a base board, a flexible printed board and a substrate; wherein, at least one semiconductor optical device is disposed on the substrate; the semiconductor optical device is electrically connected with the substrate through wires; a lower surface of the substrate is adhered to and fixed on an upper surface of the flexible printed board; the flexible printed board is provided with internal leads and external leads; the internal leads are electrically connected with the substrate through wires; a lower surface of the flexible printed board is adhered to and fixed on the base board; a glass baffle is provided to form a window in front of a light-emitting surface or a light-receiving surface of the semiconductor optical device; a focusing lens is adhered to the window of the glass baffle and is coupled into an optical path of the semiconductor optical device; the substrate and the semiconductor optical device thereon, the wires, and the internal leads on the flexible printed board are encased with packaging material.

2. The low cost surface mount packaging structure for semiconductor optical device according to claim 1, wherein, the semiconductor optical device is a photographic device or a luminescent device.

3. The low cost surface mount packaging structure for semiconductor optical device according to claim 1, wherein, the substrate comprises an upper layer and a lower layer; the lower layer is made of material with high heat conductivity and low Thermal Coefficient of Expansion; the upper layer is a wire routing layer, which is electrically connected with the semiconductor optical device on the substrate, and is made of conductive material.

4. The low cost surface mount packaging structure for semiconductor optical device according to claim 3, wherein, the material with high heat conductivity and low Thermal Coefficient of Expansion is aluminium nitride; and the conductive material is gold.

5. The low cost surface mount packaging structure for semiconductor optical device according to claim 1, wherein, the semiconductor optical device is connected with the substrate by means of eutectic welding and wire bonding.

6. The low cost surface mount packaging structure for semiconductor optical device according to claim 1, wherein, the substrate is adhered to the flexible printed board with conductive adhesive; the flexible printed board is adhered to the base board with conductive adhesive, and wherein the conductive adhesive is silver paste.

7. The low cost surface mount packaging structure for semiconductor optical device according to claim 1, wherein, one substrate or multiple substrates arranged are disposed on the flexible printed board, the internal leads of the flexible printed board are electrically connected with a wire routing layer of the substrate.

8. The low cost surface mount packaging structure for semiconductor optical device according to claim 1, wherein, the base board is made of tungsten copper; the packaging material is silica gel; and the wires are made of gold.

9. A packaging method for the low cost surface mount packaging structure for semiconductor optical device according to claim 1, comprising the following steps:
step 1, bonding a semiconductor optical device by means of eutectic welding and wire bonding onto a wire routing layer of a substrate;
step 2, electrically connecting the semiconductor optical device with the substrate through wires by means of wire bonding;
step 3, fixing a lower surface of a flexible printed board onto a base board with conductive adhesive; and getting the adhesive cured;
step 4, fixing a lower layer of the substrate onto an upper surface of the flexible printed board with conductive adhesive; and getting the adhesive cured;
step 5, electrically connecting internal leads of the flexible printed board with the wire routing layer of the substrate through wires by means of wire bonding;
step 6, installing a glass baffle to form a window in front of a light-emitting surface or a light receiving surface of the semiconductor optical device for light inputting or light outputting;
step 7, encasing the semiconductor optical device, the wires on a surface where the semiconductor optical device is disposed, the wire routing layer of the substrate and the internal leads of the flexible printed board with packaging material, the packaging material fills all space in the optical path evenly; and getting the packaging material cured; and
step 8, adhering a focusing lens to the window of the glass baffle; and coupling the focusing lens into the optical path of the semiconductor optical device.

10. The packaging method according to claim 9, wherein, the wires in step 2 and step 5 are made of gold; the conductive adhesive in step 3 and step 4 is silver paste; and the packaging material in step 7 is silica gel.
